(19) United States
(12) Patent Application Publication
(10) Pub. No.: US 2025/0174282 A1
(43) Pub. Date: May 29, 2025

(54) OPERATION METHOD OF MEMORY, MEMORY, AND MEMORY SYSTEM

(71) Applicant: YANGTZE MEMORY TECHNOLOGIES CO., LTD., Wuhan (CN)

(72) Inventors: Wei Qi, Wuhan (CN); Junbao Wang, Wuhan (CN); Da Li, Wuhan (CN); Yaoyao Tian, Wuhan (CN); Ya Wang, Wuhan (CN); Kaikai You, Wuhan (CN)

(21) Appl. No.: 18/606,904

(22) Filed: Mar. 15, 2024

(30) Foreign Application Priority Data
Nov. 24, 2023 (CN) 202311591073.8

(51) Int. Cl. G11C 16/28; G11C 16/04; G11C 16/08

(52) U.S. Cl. CPC G11C 16/28; G11C 16/0433; G11C 16/08

(57) ABSTRACT

According to one aspect of the present disclosure, a method of operating a memory is provided. An example method may include, in a prepulse operation, applying a first voltage to unselected upper select line coupled with the upper select transistor of unselected memory string to turn off the upper select transistor, and applying a second voltage to unselected lower select line coupled with lower select transistor of the unselected memory string to turn on the lower select transistor. The method may include applying a pass voltage to unselected word line. The method may include applying a third voltage to the dummy word line coupled with the dummy memory cell in the at least one group of dummy memory cells to turn off the corresponding dummy memory cell. A stage of applying the pass voltage and a stage of applying the third voltage temporally overlap in part.

### CROSS-REFERENCE TO RELATED APPLICATIONS

This application claims the benefit of priority to Chinese Application No. 202311591073.8, filed on Nov. 24, 2023, the content of which is incorporated herein by reference in its entirety.

### TECHNICAL FIELD

The present disclosure relates to the technical field of semiconductors, and particularly to a method of operating a memory, a memory, and a memory system.

### BACKGROUND

A three-dimensional memory typically includes a stacked memory array and a peripheral circuit. The peripheral circuit may apply a program voltage or read voltage to the memory array, so as to read or write storage information.

With the development of semiconductor technologies, the number of stack layers of the three-dimensional memory increases continuously, and requirements for controlling the memory arrays by the peripheral circuit become increasingly high.

### SUMMARY

According to one aspect of the present disclosure, a method of operating a memory is provided. The method may include, in a prepulse operation, applying a first voltage to unselected upper select lines coupled with upper select transistors of unselected memory strings, so as to turn off the upper select transistors of the unselected memory strings, and applying a second voltage to unselected lower select lines coupled with lower select transistors of the unselected memory strings, so as to turn on the lower select transistors of the unselected memory strings. The method may include applying a pass voltage to unselected word lines. The method may include applying a third voltage to the dummy word line coupled with the dummy memory cells in the at least one group of dummy memory cells, so as to turn off the corresponding dummy memory cells. A stage of applying the pass voltage to the unselected word lines and a stage of applying the third voltage to the dummy word line coupled with the dummy memory cells in the at least one group of dummy memory cells may temporally overlap in part. The memory may include a memory block including a plurality of memory strings. Each of the memory strings may include the upper select transistor, a plurality of memory cells, and a lower select transistor sequentially connected in series. The plurality of memory cells may include at least two groups of memory cells and a group of dummy memory cells located between any two adjacent groups of the memory cells. The memory may include a plurality of word lines. Each of the word lines may be coupled with corresponding memory cells. The memory may include at least one dummy word line. Each dummy word line may be coupled with corresponding dummy memory cells. The memory may include an upper select line coupled with a corresponding upper select transistor. The memory may include a lower select line coupled with a corresponding lower select transistor.

In some implementations, the applying the pass voltage to the unselected word lines may include, in a first stage, ramping up a voltage on the unselected word lines to the pass voltage. In some implementations, the applying the pass voltage to the unselected word lines may include, in a second stage, stabilizing the voltage on the unselected word lines at the pass voltage. In some implementations, the first stage and a process of applying the third voltage to the dummy word line coupled with the dummy memory cells in the at least one group of dummy memory cells may overlap temporally.

In some implementations, the method may further include, in the second stage, applying a fourth voltage to the at least one dummy word line to turn on the corresponding dummy memory cells.

In some implementations, the applying the third voltage to the dummy word line coupled with the dummy memory cells in the at least one group of dummy memory cells may include, in the first stage, applying the third voltage to a dummy word line coupled with the dummy memory cells in the group of dummy memory cells nearest to the lower select transistor, and applying the fourth voltage to a dummy word line coupled with the dummy memory cells in other groups of dummy memory cells.

In some implementations, the plurality of memory cells may include a first group of memory cells, a second group of memory cells, a third group of memory cells, a first group of dummy memory cells located between the first group of memory cells and the second group of memory cells, and a second group of dummy memory cells located between the second group of memory cells and the third group of memory cells. In some implementations, the applying the third voltage to the dummy word line coupled with the dummy memory cells in the at least one group of dummy memory cells may include, in the first stage, applying the third voltage to a dummy word line coupled with the dummy memory cells in one of the first group of dummy memory cells and the second group of dummy memory cells, and applying the fourth voltage to a dummy word line coupled with the dummy memory cells in the other one of the first group of dummy memory cells and the second group of dummy memory cells. In some implementations, the applying the third voltage to the dummy word line coupled with the dummy memory cells in the at least one group of dummy memory cells may include, in the first stage, applying the third voltage to the dummy word lines coupled with the dummy memory cells in the first group of dummy memory cells and the second group of dummy memory cells.

In some implementations, a plurality of lower select transistors located at the same level in the different memory strings in the memory block may be connected to each other and coupled to the same lower select line.

In some implementations, the method may include, in the prepulse operation, applying the second voltage to a selected upper select line coupled with an upper select transistor of a selected memory string.

In some implementations, the method may include, in the prepulse operation, applying the pass voltage or a fifth voltage to the selected word line.

In some implementations, the prepulse operation may be prior to a verify operation. In some implementations, the prepulse operation may be prior to a read operation. In some implementations, the prepulse operation may be prior to a program operation.

In some implementations, the method may include, in the verify operation, applying the second voltage to an upper select transistor of a selected memory string, applying the first voltage to the upper select transistors of the unselected memory strings, and applying the second voltage to lower select transistors of both the selected memory string and the unselected memory strings. In some implementations, the method may include, in the verify operation, applying a verify voltage to the selected word line, applying the pass voltage to the unselected word lines, and applying a fourth voltage to the dummy word lines coupled with the dummy memory cells in all the groups of dummy memory cells.

According to another aspect of the present disclosure, a memory is provided. The memory may include a memory block including a plurality of memory strings. Each of the memory strings may include an upper select transistor, a plurality of memory cells, and a lower select transistor sequentially connected in series. The plurality of memory cells may include at least two groups of memory cells and a group of dummy memory cells located between any two adjacent groups of the memory cells. The memory may include a plurality of word lines. Each of the word lines may be coupled with corresponding memory cells. The memory may include at least one dummy word line. Each dummy word line may be coupled with corresponding dummy memory cells. The memory may include an upper select line coupled with a corresponding upper select transistor. The memory may include a lower select line coupled with a corresponding lower select transistor. The memory may include a peripheral circuit coupled with the plurality of word lines, the at least one dummy word line, the upper select line, and the lower select line. The peripheral circuit may be configured to, in a prepulse operation, apply a first voltage to unselected upper select lines coupled with the upper select transistors of unselected memory strings, so as to turn off the upper select transistors of the unselected memory strings, and apply a second voltage to unselected lower select lines coupled with lower select transistors of the unselected memory strings, so as to turn on the lower select transistors of the unselected memory strings. The peripheral circuit may be configured to apply a pass voltage to unselected word lines. The peripheral circuit may be configured to apply a third voltage to the dummy word line coupled with the dummy memory cells in the at least one group of dummy memory cells, so as to turn off the corresponding dummy memory cells. A process of applying the pass voltage to the unselected word lines and a stage of applying the third voltage to the dummy word line coupled with the dummy memory cells in the at least one group of dummy memory cells to turn off the corresponding dummy memory cells may temporally overlap in part.

In some implementations, the peripheral circuit may be configured to, in a first stage, ramp up a voltage on the unselected word lines to the pass voltage. In some implementations, the peripheral circuit may be configured to, in a second stage, stabilize the voltage on the unselected word lines at the pass voltage. In some implementations, the first stage and a process of applying the third voltage to the dummy word line connected with the dummy memory cells in the at least one group of dummy memory cells may overlap temporally.

In some implementations, the peripheral circuit may be configured to, in the second stage, apply a fourth voltage to the at least one dummy word line to turn on all the dummy memory cells.

In some implementations, the peripheral circuit may be configured to, in the first stage, apply the third voltage to a dummy word line coupled with the dummy memory cells in the group of dummy memory cells nearest to the lower select transistor, and apply the fourth voltage to a dummy word line coupled with the dummy memory cells in other groups of dummy memory cells.

In some implementations, the plurality of memory cells may include a first group of memory cells, a second group of memory cells, a third group of memory cells, a first group of dummy memory cells located between the first group of memory cells and the second group of memory cells, and a second group of dummy memory cells located between the second group of memory cells and the third group of memory cells. In some implementations, the peripheral circuit may be configured to, in the first stage, apply the third voltage to a dummy word line coupled with the dummy memory cells in one of the first group of dummy memory cells and the second group of dummy memory cells, and apply the fourth voltage to a dummy word line coupled with the dummy memory cells in the other one of the first group of dummy memory cells and the second group of dummy memory cells. In some implementations, the peripheral circuit may be configured to, in the first stage, apply the third voltage to the dummy word lines coupled with the dummy memory cells in the first group of dummy memory cells and the second group of dummy memory cells.

In some implementations, a plurality of lower select transistors located at the same level in the different memory strings in the memory block may be connected to each other and coupled to the same lower select line.

In some implementations, the peripheral circuit may be configured to, in the prepulse operation, apply the second voltage to a selected upper select line coupled with an upper select transistor of a selected memory string.

In some implementations, the peripheral circuit may be configured to, in the prepulse operation, apply the pass voltage or a fifth voltage to the selected word line.

In some implementations, the peripheral circuit may be configured to perform the prepulse operation prior to a verify operation. In some implementations, the peripheral circuit may be configured to perform the prepulse operation prior to a read operation. In some implementations, the peripheral circuit may be configured to perform the prepulse operation prior to a program operation.

In some implementations, the peripheral circuit may be configured to, in the verify operation, apply the second voltage to an upper select transistor of a selected memory string, apply the first voltage to the upper select transistors of the unselected memory strings, and apply the second voltage to lower select transistors of both the selected memory string and the unselected memory strings. In some implementations, the peripheral circuit may be configured to, in the verify operation, apply a verify voltage to the selected word line, and apply a fourth voltage to the unselected word lines and the dummy word lines coupled with the dummy memory cells in all the groups of dummy memory cells.

In some implementations, the memory may be a NAND memory.

According to yet another aspect of the present disclosure, a memory system is provided. The memory system may include a memory. The memory may include a memory block including a plurality of memory strings. Each of the memory strings may include an upper select transistor, a plurality of memory cells, and a lower select transistor sequentially connected in series. The plurality of memory cells may include at least two groups of memory cells and a group of dummy memory cells located between any two adjacent groups of the memory cells. The memory may include a plurality of word lines. Each of the word lines may be coupled with corresponding memory cells. The memory may include at least one dummy word line. Each dummy word line may be coupled with corresponding dummy memory cells. The memory may include an upper select line coupled with a corresponding upper select transistor. The memory may include a lower select line coupled with a corresponding lower select transistor. The memory may include a peripheral circuit coupled with the plurality of word lines, the at least one dummy word line, the upper select line, and the lower select line. The peripheral circuit may be configured to, in a prepulse operation, apply a first voltage to unselected upper select lines coupled with the upper select transistors of unselected memory strings, so as to turn off the upper select transistors of the unselected memory strings, and apply a second voltage to unselected lower select lines coupled with lower select transistors of the unselected memory strings, so as to turn on the lower select transistors of the unselected memory strings. The peripheral circuit may be configured to apply a pass voltage to unselected word lines. The peripheral circuit may be configured to apply a third voltage to the dummy word line coupled with the dummy memory cells in the at least one group of dummy memory cells, so as to turn off the corresponding dummy memory cells. A process of applying the pass voltage to the unselected word lines and a stage of applying the third voltage to the dummy word line coupled with the dummy memory cells in the at least one group of dummy memory cells to turn off the corresponding dummy memory cells may temporally overlap in part. The memory system may include a controller coupled to the memory and configured to control the memory.

The examples of the present disclosure provide a method of operating a memory, a memory, and a memory system. The memory includes: a memory block including a plurality of memory strings, each of the memory strings including the upper select transistor, a plurality of memory cells, and a lower select transistor sequentially connected in series, the plurality of memory cells including at least two groups of memory cells and a group of dummy memory cells located between any two adjacent groups of the memory cells; a plurality of word lines, each of the word lines coupled with corresponding memory cells; at least one dummy word line, each dummy word line coupled with corresponding dummy memory cells; an upper select line coupled with a corresponding upper select transistor; and a lower select line coupled with a corresponding lower select transistor. The operation method includes: in a prepulse operation, applying a turn-off first voltage to unselected upper select lines coupled with the upper select transistors of unselected memory strings, so as to turn off the upper select transistors of the unselected memory strings, and applying a second turn-on voltage to unselected lower select lines coupled with lower select transistors of the unselected memory strings, so as to turn on the lower select transistors of the unselected memory strings; applying a pass voltage to unselected word lines; and applying a third turn-off voltage to the dummy word line coupled with the dummy memory cells in the at least one group of dummy memory cells, so as to turn off the corresponding dummy memory cells. A stage of applying the pass voltage to the unselected word lines and a stage of applying the third turn-off voltage to the dummy word line coupled with the dummy memory cells in the at least one group of dummy memory cells may temporally overlap in part. In the examples of the present disclosure, in the prepulse operation, the first voltage is applied to the upper select transistors of the unselected memory strings, and the stage of applying the pass voltage to the unselected word lines and the stage of applying the third voltage to the dummy word line coupled with the dummy memory cells overlap in part, so that a channel potential of the group of memory cells located on the dummy memory cells coupled with the dummy word line to which the third voltage is applied is boosted, thereby shortening program time and improving program efficiency. The examples of the present disclosure are applicable to a memory structure with no physical Bottom Select Gate Cut (BSG CUT), and may shorten the program time and improve the program efficiency.

### BRIEF DESCRIPTION OF THE DRAWINGS

FIG. 1 is a schematic partial sectional structural diagram of a memory, according to an example of the present disclosure;

FIG. 2 is a voltage waveform timing diagram of a program operation of the memory and a channel potential diagram of an unselected memory string, according to an example of the present disclosure;

FIG. 3 is a flow diagram of a method of operating a memory, according to an example of the present disclosure;

FIG. 4 is a schematic partial sectional structural diagram of a memory, according to an example of the present disclosure;

FIG. 5 is a schematic circuit diagram of a memory, according to an example of the present disclosure;

FIG. 6 is an equivalent partial circuit diagram of a memory, according to an example of the present disclosure;

FIG. 7 is a voltage waveform timing diagram of a program operation of a memory, according to an example of the present disclosure;

FIG. 8 is a partial circuit diagram of a memory string, according to an example of the present disclosure;

FIG. 9 is a voltage waveform timing diagram of a program operation of a memory, according to an example of the present disclosure;

FIG. 10 is a structural block diagram of a memory, according to an example of the present disclosure;

FIG. 11 is a block diagram of a memory including an array of memory cells and a peripheral circuit, according to an example of the present disclosure;

FIG. 12 is a block diagram of a memory system, according to an example of the present disclosure;

FIG. 13a is a schematic diagram of a memory card, according to an example of the present disclosure; and

FIG. 13b is a schematic diagram of a solid state drive (SSD), according to an example of the present disclosure.

### DETAILED DESCRIPTION

The technical solutions in implementations of the present disclosure will be described below clearly and completely in conjunction with the implementations and the drawings of the present disclosure. Apparently, the implementations described are only part, but not all, of the implementations of the present disclosure. All other implementations obtained by those of ordinary skill in the art based on the implementations in the present disclosure without creative work shall fall within the scope of protection of the present disclosure.

In the description below, many specific details are presented to provide a more thorough understanding of the present disclosure. However, it is apparent to those skilled in the art that the present disclosure may be practiced without one or more of these details. In other examples, in order to avoid confusing with the present disclosure, some technical features well-known in the art are not described; that is, not all features of actual examples are described herein, and well-known functions and structures are not described in detail.

In the drawings, sizes and relative sizes of layers, areas and elements may be exaggerated for clarity. Like reference numerals denote like elements throughout.

It is to be understood that when an element or a layer is referred to as being “on”, “adjacent to”, “connected to”, or “coupled to” other elements or layers, it may be directly on, adjacent to, connected to, or coupled to the other elements or layers, or one or more intervening elements or layers may be present. In contrast, when an element is referred to as being “directly on”, “immediately adjacent to”, “directly connected to”, or “directly coupled to” other elements or layers, no intervening elements or layers are present. It is to be understood that, although the terms first, second, and third, etc., may be used to describe various elements, components, areas, layers and/or portions, these elements, components, areas, layers and/or portions should not be limited by these terms. These terms are only used to distinguish one element, component, area, layer or portion from another element, component, area, layer or portion. Thus, a first element, component, area, layer or portion discussed below may be represented as a second element, component, area, layer or portion, without departing from the teachings of the present disclosure. When the second element, component, region, layer or portion is discussed, it does not mean that the first element, component, region, layer or portion is necessarily present in the present disclosure.

The spatially relative terms, such as “beneath”, “below”, “lower”, “under”, “above”, “upper”, and the like, may be used herein for ease of description to describe a relationship of one element or feature with respect to other elements or features as illustrated in the figures. It is to be understood that the spatially relative terms are intended to further encompass different orientations of a device in use or operation in addition to the orientation depicted in the figures. For example, if a device in the drawings is turned over, then an element or a feature described as “below other elements”, or “under other elements”, or “beneath other elements” will be orientated to be “above” the other elements or features. Thus, the exemplary terms, “below” and “beneath”, may include both upper and lower orientations. The device may be orientated otherwise (rotated by 90 degrees or other orientations), and the spatially descriptive terms used herein are interpreted accordingly.

The terms used herein are only intended to describe the particular examples, and are not used as limitations of the present disclosure. As used herein, unless otherwise indicated expressly in the context, “a”, “an” and “the” in a singular form are also intended to include a plural form. It is also to be understood that the terms “consist of” and/or “comprise”, when used in this specification, determine the presence of a feature, integer, step, operation, element and/or component, but do not preclude the presence or addition of one or more of other features, integers, steps, operations, elements, components, and/or groups. As used herein, the term “and/or” includes any and all combinations of the listed relevant items.

In order to understand the present disclosure thoroughly, detailed operations and detailed structures will be proposed in the following description to set forth the technical solution of the present disclosure. The detailed descriptions of the preferable examples of the present disclosure are as follows. However, the present disclosure may also have other implementations in addition to these detailed descriptions.

In order to increase ramp rates of a drive voltage and a word line voltage, a physical bottom select gate cut may be added to a process. In an example, a three-dimensional memory includes a stacked memory array and a peripheral circuit. The memory array further includes a plurality of memory blocks arranged in an array, and the memory blocks may be minimum erasable units of the three-dimensional memory. The memory block includes a plurality of memory strings arranged vertically, and each of the memory strings further includes a lower select transistor structure and the upper select transistor structure. By forming one or more physical bottom select gate cuts in a bottom selective gate, one memory block may be segmented into a plurality of finger memory regions, each of the finger memory regions including a plurality of memory strings. After a subsequent gate replacement process, the upper select transistor structure and the lower select transistor structure may be transformed into a Top Selective Gate (TSG) and a Bottom Selective Gate (BSG). At this time, each bottom selective gate controls a corresponding finger memory region individually using the finger memory region as a unit.

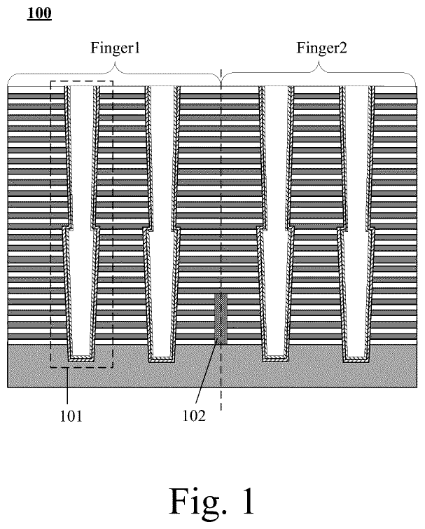

FIG. 1 is a schematic partial sectional structural diagram of a memory in an example of the examples of the present disclosure. As shown in FIG. 1, the schematic partial diagram of the memory 100 illustrates four rows of memory strings 101. The four rows of memory strings 101 are divided into two finger memory regions, which are Finger1 and Finger2 respectively, through a solution of the physical bottom select gate cut. Each finger memory region contains two adjacent rows of memory strings 101. Through the lower select transistor cut 102, the finger memory regions in the memory may be isolated physically, so as to control each finger memory region individually through the bottom selective gate of each finger memory region.

It is to be noted that a number of rows of the memory strings provided in FIG. 1 is merely an example illustration, which is not used to limit the number of rows of the memory strings contained in one finger memory region of the memory in the present disclosure. In practical applications, the number of rows of the memory strings contained in one finger memory region may be adjusted to, e.g., 2, 4, 8, and 16, etc., according to practical situations.

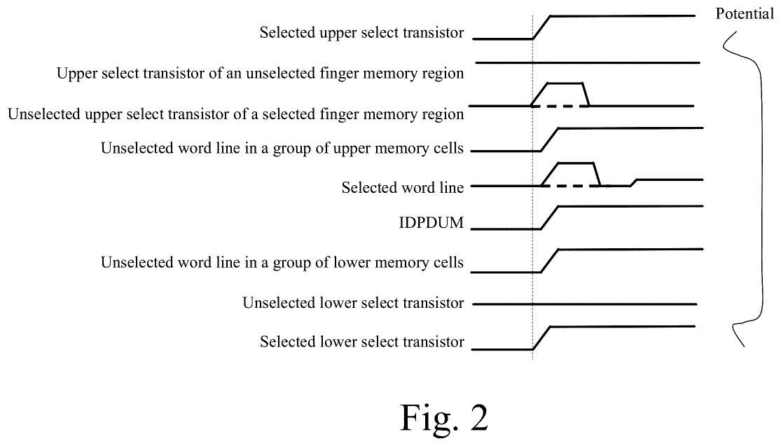

FIG. 2 is a voltage waveform timing diagram of a program operation of the memory and a channel potential diagram of an unselected memory string, according to an example of the present disclosure.

In an example, each of memory strings of the three-dimensional memory may include a plurality groups of stacked memory cells, and the plurality groups of memory cells are connected in series. Due to limitations of an etching process, when a number of layers of the memory string increases, multiple stacking processes are required to form a plurality of decks, and the memory string including the plurality groups of memory cells are formed through multiple etching processes. In some examples, two adjacent groups of the memory cells are connected tightly through a group of dummy memory cells, thereby forming one memory string. Here, each dummy memory cell in the group of dummy memory cells may have a transitional function in the process and may not be used to store data. In an example, the memory string to be programmed is located in a selected finger memory region in the memory block, and other finger memory region than the selected finger memory region in the memory block is an unselected finger memory region. Each memory string includes two groups of memory cells connected longitudinally in series, which are an upper deck and a lower deck respectively, and each group of memory cells includes a plurality of memory cells. In some examples, a group of dummy memory cells is further included between the upper deck and the lower deck. The group of dummy memory cells includes a plurality of dummy memory cells, and the dummy memory cells are coupled with a dummy word line (e.g., an Inter Deck Plug Dummy (IDPDUM) word line). Each memory string further includes the upper select transistor, and the respective memory string in the finger memory region may be selected respectively through the upper select transistor. Each finger memory region includes a lower select transistor, and the respective finger memory region may be selected through the lower select transistor.

With continued reference to FIG. 2, during a prepulse stage, a turn-on voltage is applied to an upper select transistor of a selected memory string in the selected finger memory region. The turn-on voltage may be greater than a threshold voltage of the upper select transistor; a turn-off voltage is applied to the upper select transistor of a memory string in the unselected finger memory region. The turn-off voltage may be 0 V; the turn-off voltage is applied to a lower select transistor of the unselected finger memory region; and the turn-on voltage is applied to a selected lower select transistor in the selected finger memory region. The upper select transistor and the lower select transistor of the unselected finger memory region are turned off, so that a channel of the unselected finger memory region is in a floating state. A pass voltage is applied to unselected word lines, and the pass voltage Vₚₐₛₛ may be a turn-on voltage of the memory cell. As a voltage on the unselected word lines rises from 0 V to the pass voltage, a potential is generated by coupling in the channel of the memory string in the unselected finger memory region, thereby increasing a ramp rate of the drive voltage and shortening a program time period (tPROG). It is to be noted that in the example shown in FIG. 2, using the solution of the physical bottom select gate cut, during the prepulse stage, an increase in the channel potential of the memory string in the unselected finger memory region can be realized just by applying the respective turn-off voltage to the unselected upper select transistor and the unselected lower select transistor of the memory string in the unselected finger memory region, while there is no requirement for a voltage applied to the word line or the dummy word line with which the memory cell in each memory string is coupled. Therefore, descriptions of a word line voltage and a dummy word line voltage in the example shown in FIG. 2 are omitted here.

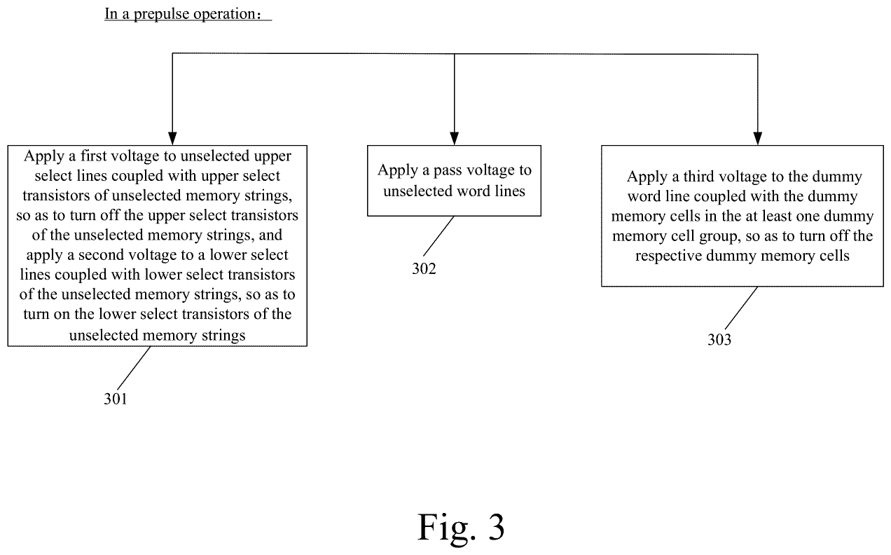

FIG. 3 is a flow diagram of a method of operating a memory, according to an example of the present disclosure.

As shown in FIG. 3, the examples of the present disclosure provide a method of operating a memory. The memory includes a memory block including a plurality of memory strings, each of the memory strings including the upper select transistor, a plurality of memory cells, and a lower select transistor sequentially connected in series. The plurality of memory cells include at least two groups of memory cells and a group of dummy memory cells located between any two adjacent groups of the memory cells. The memory includes a plurality of word lines, each of the word lines coupled with corresponding memory cells; at least one dummy word line, each dummy word line coupled with corresponding dummy memory cells. The memory includes an upper select line coupled with a corresponding upper select transistor. The memory includes a lower select line coupled with a corresponding lower select transistor.

The method of operating a memory includes, at operation 301, in a prepulse operation, applying a first voltage to unselected upper select lines coupled with the upper select transistors of unselected memory strings, so as to turn off the upper select transistors of the unselected memory strings, and applying a second voltage to unselected lower select lines coupled with lower select transistors of the unselected memory strings, so as to turn on the lower select transistors of the unselected memory strings. At operation 302, the method may include applying a pass voltage to unselected word lines. At operation 303, the method may include applying a third voltage to the dummy word line coupled with the dummy memory cells in the at least one group of dummy memory cells, so as to turn off the corresponding dummy memory cells. A stage of applying the pass voltage to the unselected word lines and a stage of applying the third voltage to the dummy word line coupled with the dummy memory cells in the at least one group of dummy memory cells temporally overlap in part.

In the examples of the present disclosure, an array of memory cells in one memory block may be provided in the form of an array of memory strings (such as NAND memory strings). In some implementations, each memory string may extend vertically, and each memory string may include a plurality of memory cells connected in series. Each memory cell or dummy memory cell may be a floating memory cell having a floating gate transistor or a charge trap memory cell having a charge trap transistor. The upper select transistor and the lower select transistor may be conventional MOS transistors or charge trap MOS transistors, which are not limited particularly by the present disclosure.

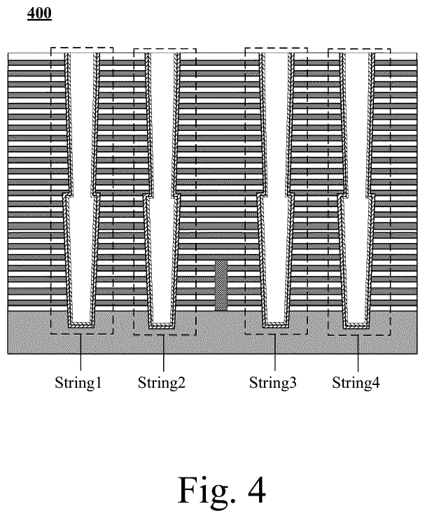

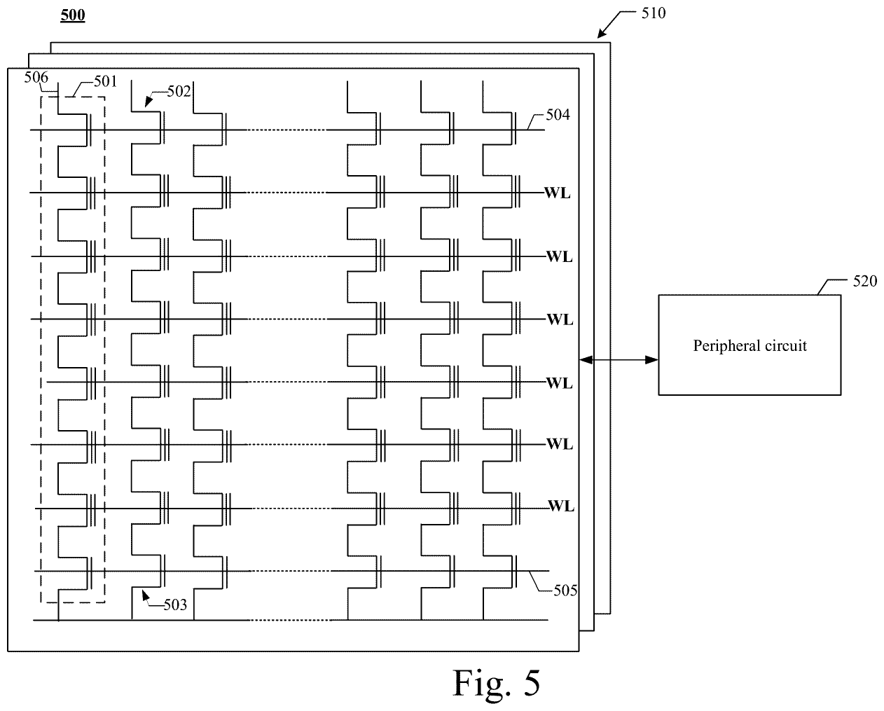

FIG. 4 is a schematic partial sectional structural diagram of a memory, according to one example of the present disclosure. FIG. 5 is a schematic circuit diagram of a memory, according to one example of the present disclosure.

As shown in FIG. 4, in an example, one memory block in the memory may include four rows of memory strings, which are String1, String2, String3, and String4, respectively. Referring to FIG. 5, memory 500 includes an array of memory cells 510 and a peripheral circuit 520 coupled with the array of memory cells. The array of memory cells 510 includes a plurality of memory strings 501. Each memory string 501 may include a lower select transistor 503 at a source terminal thereof and the upper select transistor 502 at a drain terminal thereof. The lower select transistor 503 and the upper select transistor 502 may be configured to activate the selected memory string 501 during read and program operations. During a prepulse operation, one or more memory strings 501 may be selected via an upper select line 504 (also referred to as a String Select Line (SSL)). For example, one row of memory strings 501 in the memory block may be selected.

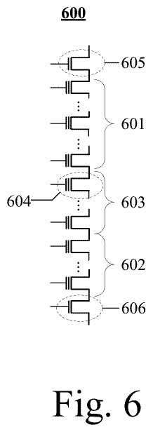

FIG. 6 is a partial circuit diagram of the memory string, according to an example of the present disclosure.

As shown in FIG. 6, the memory string 600 includes two groups of memory cells connected in series and a group of dummy memory cells 603 located between the two groups of memory cells. In an example, the memory string 600 includes a first group of memory cells 601 and a second group of memory cells 602. The first group of memory cells 601 may also be referred to as an Upper Deck and the second group of memory cells 602 may also be referred to as a Lower Deck. The group of dummy memory cells 603 includes one or more dummy memory cells 604, and a dummy word line coupled with the dummy memory cells 604 is an inter deck plug dummy word line. The first group of memory cells 601 is adjacent to the upper select transistor 605, and the second group of memory cells 602 is adjacent to the lower select transistor 606.

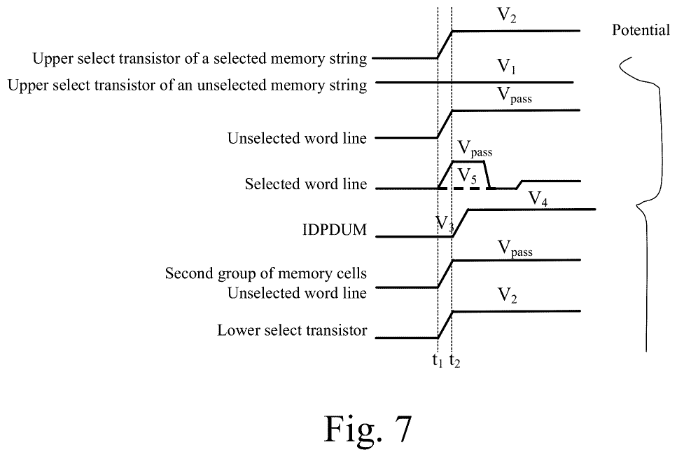

FIG. 7 is a voltage waveform timing diagram of a program operation of the memory, according to an example of the present disclosure.

With reference to FIG. 4 to FIG. 7, during a prepulse operation stage, the pass voltage Vₚₐₛₛ may be applied to the unselected word lines. For example, the pass voltage Vₚₐₛₛ is applied to the unselected word lines corresponding to the memory cells in the upper deck and the unselected word lines corresponding to the memory cells in the lower deck, and the pass voltage Vₚₐₛₛ may be greater than a threshold voltage of the corresponding memory cells. In an example, pass voltage Vₚₐₛₛ may be 5 V to 7 V, and the threshold voltage of the corresponding memory cells may be 2 V to 3 V. Meanwhile, a first voltage V₁ may be applied to the upper select transistors of the unselected memory strings, the second voltage V₂ may be applied to the lower select transistors of the unselected memory strings, and the third voltage V₃ may be applied to the dummy word line (DWL) coupled with the dummy memory cells in the at least one group of dummy memory cells. The first voltage V₁ and the third voltage V₃ may be 0 V, and the second voltage V₂ may be greater than a threshold voltage of the upper select transistor.

In the prepulse operation, the stages of applying the first voltage V₁ and applying the pass voltage Vₚₐₛₛ to the unselected word lines and a stage of applying the third voltage V₃ to the dummy word line coupled with the dummy memory cells in the group of dummy memory cells between the two groups of memory cells temporally overlap in part. As such, in the unselected memory strings, the upper select transistors of the unselected memory strings is completely turned off with respect to the dummy memory cells corresponding to the dummy word line to which the third voltage is applied, and a portion of channels in the unselected memory strings are in a floating state. At this time, during application of the pass voltage Vₚₐₛₛ to the unselected word lines, as a voltage on the unselected word lines rises from 0 V to the pass voltage Vₚₐₛₛ, a potential is generated by coupling in the channels of the unselected memory strings. In an example, a first potential is generated by coupling in a channel of the upper deck of the unselected memory strings. In the examples of the present disclosure, since the third voltage is applied to the dummy word line coupled with the dummy memory cells above the lower deck of the unselected memory strings, a second potential may also be generated by coupling in a channel of the lower deck of the unselected memory strings. The first potential is higher than the second potential. Thus, the higher potential generated by coupling in the channel of the upper deck of the unselected memory strings may increase the ramp rate of the word line voltage, thereby improving program time.

In the examples of the present disclosure, a timing of applying voltages to the word line, the dummy word line, the upper select transistor, and the lower select transistor may be controlled through a timing controller, so that a higher potential is generated by coupling in the channel of the group of memory cells above the dummy memory cells corresponding to the dummy word line to which the third voltage is applied. That is, the potential in the channel is boosted to a certain level. The boosting of the channel potential may increase the ramp rate of the word line voltage. During program of the memory cells above the dummy memory cells corresponding to the dummy word line to which the third voltage is applied, the word line voltage may be applied to a selected word line corresponding to the memory cells; and at this time, a program speed may be increased significantly and the program time may be shortened significantly.

In the examples of the present disclosure, the stage of applying the pass voltage Vₚₐₛₛ to the unselected word lines and the stage of applying the third voltage V₃ to the dummy word line coupled with the dummy memory cells in the at least one group of dummy memory cells temporally overlapping in part includes: the stage of applying the third voltage V₃ to the dummy word line coupled with part of the dummy memory cells in the at least one group of dummy memory cells or the stage of applying the third voltage V₃ to the dummy word line coupled with all of the dummy memory cells in the at least one group of dummy memory cells and the stage of applying the pass voltage Vₚₐₛₛ to the unselected word lines overlap in part.

The examples of the present disclosure may achieve an improved cost reduction while shortening the program time period, while at the same time improving operability. Furthermore, with continuous development of memories, in cases of an increasingly reduced size of the memories, an increasingly reduced width of a channel structure, and increasingly more channel structures contained in a memory block of the same area, such operation method is applicable to a memory structure with no BSG CUT. That is, the operation method provided by the examples of the present disclosure can replace part of the functions of the BSG CUT, so that the channel potential of the group of memory cells located on the dummy memory cells coupled with the dummy word line to which the third voltage is applied is boosted, thereby shortening the program time and improving the program efficiency.

It is to be noted that the above selected word line and the unselected word line are intended to facilitate distinguishing between different operations corresponding to a program process, and do not indicate the existence of two different types of word lines. The selected word line may be any one of word lines coupled in the memory array, and selected word lines corresponding to different program processes may be the same word line or may be different word lines. A word line required to be inhibited from being programmed is an unselected word line in a current program process. The same rule as above is applicable to the selected memory string and the unselected memory strings.

In the examples of the present disclosure, the applying the pass voltage to the unselected word lines includes: in a first stage, ramping up a voltage on the unselected word lines to the pass voltage; and in a second stage, stabilizing the voltage on the unselected word lines at the pass voltage. The first stage and the stage of applying the third voltage to the dummy word line coupled with the dummy memory cells in the at least one group of dummy memory cells overlap temporally.

With continued reference to FIG. 6, the application of the pass voltage to the unselected word lines includes two stages, which are the first stage and the second stage respectively. The first stage is between a time instance t1 and a time instance t2, and the second stage is after the time instance t2. In the first stage, the unselected word line is charged to the pass voltage Vₚₐₛₛ, and in the second stage, the voltage of the unselected word line is maintained at Vₚₐₛₛ. Moreover, in the first stage, the third voltage V₃ is applied to the dummy word line coupled with the dummy memory cells in the at least one group of dummy memory cells. It is to be noted that, for the dummy memory cells corresponding to the dummy word line to which the third voltage V₃ is applied in the first stage, the third voltage V₃ may also be applied, prior to the first stage, to the dummy word line coupled therewith.

In the examples of the present disclosure, the stage of applying the pass voltage Vₚₐₛₛ to the unselected word lines and the stage of applying the third voltage V₃ to the dummy word line coupled with the dummy memory cells in the at least one group of dummy memory cells temporally overlapping in part includes: in the first stage, applying the pass voltage Vₚₐₛₛ to the unselected word lines and applying the third voltage V₃ to the dummy word line coupled with the dummy memory cells in the at least one group of dummy memory cells.

As shown in FIG. 6, in the examples of the present disclosure, the method of operating a memory further includes: in the second stage, applying a fourth voltage V₄ to the at least one dummy word line to turn on the corresponding dummy memory cells.

In the examples of the present disclosure, the fourth voltage V₄ may be greater than a threshold voltage of the corresponding dummy memory cells.

In the examples of the present disclosure, the applying the third voltage to the dummy word line coupled with the dummy memory cells in the at least one group of dummy memory cells includes: in the first stage, applying the third voltage to a dummy word line coupled with the dummy memory cells in the group of dummy memory cells nearest to the lower select transistor, and applying the fourth voltage to a dummy word line coupled with the dummy memory cells in other groups of dummy memory cells.

In the examples of the present disclosure, in the first stage, the third voltage V₃ may be applied to the dummy word line coupled with all the dummy memory cells in the group of dummy memory cells nearest to the lower select transistor, or the third voltage V₃ may be applied to the dummy word line coupled with part of the dummy memory cells in the group of dummy memory cells nearest to the lower select transistor.

In the examples of the present disclosure, the third voltage may be applied to the dummy word line corresponding to the dummy memory cells in the group of dummy memory cells nearest to the lower select transistor in the unselected memory strings, so that a channel potential is generated by coupling above the dummy memory cells. With the presence of increasingly more groups of memory cells in the memory string, the channel potential generated by coupling in the unselected memory strings gradually tend to be present in the entire channel, so that the effect of increasing the ramp rate of the word line voltage is increasingly significant, resulting in an increasingly significant improvement in the program efficiency. Here, an understanding of the ramp rate of the word line voltage may be referred to FIG. 7. In FIG. 7, the time between the time instance t1 and the time instance t2 is ramp time of the word line voltage. When the difference between t2 and t1 is smaller, the shorter the ramp time of the word line voltage is, and the larger the ramp rate of the word line voltage is.

In the examples of the present disclosure, each of memory strings of the plurality of memory cells include a first group of memory cells, a second group of memory cells, a third group of memory cells, a first group of dummy memory cells located between the first group of memory cells and the second group of memory cells, and a second group of dummy memory cells located between the second group of memory cells and the third group of memory cells. The applying the third voltage to the dummy word line coupled with the dummy memory cells in the at least one group of dummy memory cells includes: in the first stage, applying the third voltage to a dummy word line coupled with the dummy memory cells in one of the first group of dummy memory cells and the second group of dummy memory cells, and applying the fourth voltage to a dummy word line coupled with the dummy memory cells in the other one of the first group of dummy memory cells and the second group of dummy memory cells; or in the first stage, applying the third voltage to the dummy word lines coupled with the dummy memory cells in the first group of dummy memory cells and the second group of dummy memory cells.

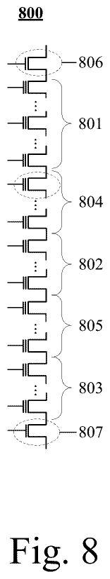

FIG. 8 is a partial circuit diagram of the memory string, according to an example of the present disclosure.

As shown in FIG. 8, the memory string 800 includes three groups of memory cells and groups of dummy memory cells. In an example, the memory string includes a first group of memory cells 801, a second group of memory cells 802, and a third second group of memory cells 803. The first group of memory cells 801 may also be referred to as an Upper Deck, the second group of memory cells 802 may also be referred to as a Middle Deck, and the third group of memory cells 803 may also be referred to as a Lower Deck. The group of dummy memory cells includes a first group of dummy memory cells 804 located between the first group of memory cells 801 and the second group of memory cells 802, and a second group of dummy memory cells 805 located between the second group of memory cells 802 and the third group of memory cells 803. The first group of memory cells 801 is adjacent to the upper select transistor 806, and the third group of memory cells 803 is adjacent to a lower select transistor 807.

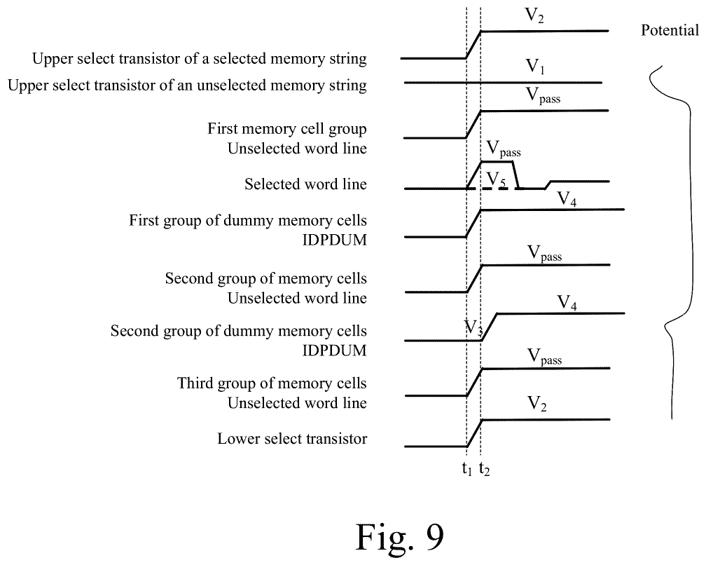

FIG. 9 is a voltage waveform timing diagram of a program operation of the memory, according to an example of the present disclosure.

With reference to FIG. 8 and FIG. 9, in the first stage (between the time instance t1 and the time instance t2), the pass voltage Vₚₐₛₛ may be applied to an unselected word line coupled with a first memory cell of the memory string, an unselected word line coupled with a second memory cell, and an unselected word line coupled with a third memory cell respectively, the first voltage V₁ is applied to the upper select transistors of the unselected memory strings, the second voltage V₂ is applied to the lower select transistors of the unselected memory strings, the third voltage V₃ is applied to a dummy word line coupled with dummy memory cells in the second group of dummy memory cells between the second group of memory cells and the third group of memory cells, and the fourth voltage V₄ is applied to a dummy word line coupled with all dummy memory cells in the first group of dummy memory cells between the first group of memory cells and the second group of memory cells. As such, channel potentials of the first group of memory cells, the second group of memory cells, and the first group of dummy memory cells of the unselected memory strings are boosted. In the first stage, the third voltage V₃ may be applied to the dummy word line coupled with all the dummy memory cells in the second group of dummy memory cells, or the third voltage V₃ may be applied to the dummy word line coupled with part of the dummy memory cells in the second group of dummy memory cells.

In another example of the present disclosure, in the first stage, the third voltage is applied to the dummy word line coupled with the dummy memory cells in the first group of dummy memory cells, and the fourth voltage is applied to the dummy word line coupled with the dummy memory cells in the second group of dummy memory cells. As such, a channel potential of the first group of memory cells of the unselected memory strings is boosted. In the first stage, the third voltage may be applied to the dummy word line coupled with all the dummy memory cells in the first group of dummy memory cells, or the third voltage may be applied to the dummy word line coupled with part of the dummy memory cells in the first group of dummy memory cells.

In another example of the present disclosure, in the first stage, the third voltage is applied to both of the dummy word line coupled with the dummy memory cells in the first group of dummy memory cells and the dummy word line coupled with the dummy memory cells in the second group of dummy memory cells. As such, the channel potential of the first group of memory cells of the unselected memory strings is boosted. Likewise, in the first stage, the third voltage may be applied to the dummy word lines coupled with all the dummy memory cells in the first group of dummy memory cells and the second group of dummy memory cells; or the third voltage may be applied to the dummy word line coupled with part of the dummy memory cells in the first group of dummy memory cells and to the dummy word line coupled with part of the dummy memory cells in the second group of dummy memory cells; or the third voltage may be applied to the dummy word line coupled with all the dummy memory cells in the first group of dummy memory cells and to the dummy word line coupled with part of the dummy memory cells in the second group of dummy memory cells; or the third voltage may be applied to the dummy word line coupled with part of the dummy memory cells in the first group of dummy memory cells and to the dummy word line coupled with all the dummy memory cells in the second group of dummy memory cells.

Referring to FIG. 8, in the examples of the present disclosure, in the first stage, compared with a case of applying the third voltage to a dummy word line coupled with dummy memory cells in a group of dummy memory cells (e.g., the first group of dummy memory cells 804) that is second nearest to the lower select transistor and applying the fourth voltage to a dummy word line coupled with dummy memory cells in the other groups of dummy memory cells (e.g., the second group of dummy memory cells 805), the case of applying the third voltage to the dummy word line coupled with the dummy memory cells in the group of dummy memory cells (e.g., the second group of dummy memory cells 805) nearest to the lower select transistor and applying the fourth voltage to the dummy word line coupled with the dummy memory cells in the other groups of dummy memory cells (e.g., the first group of dummy memory cells 804) may boost the channel potential of the unselected memory strings to a greater extent. That is, the program speed may be further improved.

In the examples of the present disclosure, the description of the memory string including two or three groups of memory cells is used as an example only, and in other examples, the memory string may include more than three groups of memory cells, which are not limited by the present disclosure.

In the examples of the present disclosure, different memory strings in the same memory block are electrically isolated from each other through different upper select transistors respectively. A plurality of lower select transistors located at the same level in the different memory strings in the memory block are connected to each other and coupled to the same lower select line.

With reference to FIG. 5 and FIG. 8, in the examples of the present disclosure, a gate of the upper select transistor of each memory string is connected with the upper select line, a source of the upper select transistor is connected with a drain of an adjacent memory cell below the upper select transistor, and a drain of the upper select transistor is connected with a Bit Line (BL) 506. That is, at a certain time instance, upper select transistors of the different memory strings may acquire different voltages. Gates of the lower select transistors of the plurality of memory strings in the same memory block are connected with the same lower select line 505 (which may also be referred to as a Ground Select Line (GSL)), a drain of the lower select transistor is connected with a source of an adjacent memory cell above the lower select transistor, and a source of the lower select transistor is connected with a source line. At a certain time instance, the lower select transistors of the plurality of memory strings in the same memory block may acquire the same voltage.

In the examples of the present disclosure, the method of operating a memory further includes: in the prepulse operation, applying the second voltage to a selected upper select line coupled with an upper select transistor of a selected memory string. In other words, in the prepulse operation, the second voltage may be applied to the upper select transistor of a certain memory string, so as to turn on the upper select transistor of the memory string, thereby causing the memory string to be selected.

In the examples of the present disclosure, the method of operating a memory further includes, in the prepulse operation, applying the pass voltage Vₚₐₛₛ or a fifth voltage V₅ to the selected word line. The fifth voltage V₅ may be a turn-off voltage.

In the examples of the present disclosure, the prepulse operation is prior to a verify operation; or the prepulse operation is prior to a read operation; or the prepulse operation is prior to a program operation.

In an example, in the method of operating a memory, the prepulse operation may be performed prior to any one or more of the verify operation, the read operation, and the program operation respectively. The prepulse operation may be also performed prior to one or more verify operations, read operations, and program operations, respectively. In an example, the prepulse operation is performed between a current program operation and a current verify operation. In another example, the prepulse operation is performed between a current verify operation and a next program operation. In the examples of the present disclosure, the prepulse operation may increase the speed of the verify, read, or program operation that is performed thereafter, thereby shortening a time period of the entire operation.

In the examples of the present disclosure, the method of operating a memory further includes, in the verify operation, applying the second voltage to an upper select transistor of a selected memory string, applying the first voltage to the upper select transistors of the unselected memory strings, and applying the second voltage to lower select transistors of both the selected memory string and the unselected memory strings; and in the verify operation, applying a verify voltage to the selected word line, applying the pass voltage to the unselected word lines, and applying the fourth voltage to the dummy word lines coupled with the dummy memory cells in all the groups of dummy memory cells.

In the examples of the present disclosure, in the verify operation, the verify voltage is applied to the selected word line to verify the threshold voltage of the memory cell, so as to determine that the memory cell is in a respective memory state. In the examples of the present disclosure, the pass voltage and the verify voltage may be determined according to actual application situations. The verify voltage may be less than the pass voltage, and the fourth voltage may be equal to the pass voltage.

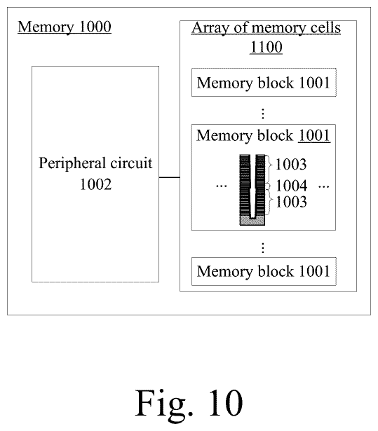

FIG. 10 is a structural block diagram of a memory, according to an example of the present disclosure.

As shown in FIG. 10, the examples of the present disclosure further provide a memory 1000. The memory 1000 includes an array of memory cells 1100 including a plurality of memory blocks 1001. Each memory block 1001 may include a plurality of memory strings. Each of the memory strings may include the upper select transistor, a plurality of memory cells, and a lower select transistor sequentially connected in series. The plurality of memory cells may include at least two groups of memory cells 1003 and a group of dummy memory cells 1004 located between any two adjacent groups of the memory cells 1003. The memory 1000 may include a plurality of word lines, each of the word lines coupled with corresponding memory cells. The memory 1000 may include at least one dummy word line. Each dummy word line may be coupled with corresponding dummy memory cells. The memory 1000 may include an upper select line coupled with a corresponding upper select transistor. The memory 1000 may include a lower select line coupled with a corresponding lower select transistor. The memory 1000 may include a peripheral circuit 1002 coupled with the plurality of word lines, the at least one dummy word line, the upper select line, and the lower select line. The peripheral circuit 1002 may be configured to in a prepulse operation, apply a first voltage to unselected upper select lines coupled with the upper select transistors of unselected memory strings, so as to turn off the upper select transistors of the unselected memory strings, and apply a second voltage to unselected lower select lines coupled with lower select transistors of the unselected memory strings, so as to turn on the lower select transistors of the unselected memory strings. The peripheral circuit 1002 may be configured to apply a pass voltage to unselected word lines. The peripheral circuit 1002 may be configured to apply a third voltage to the dummy word line coupled with the dummy memory cells in the at least one group of dummy memory cells, so as to turn off the corresponding dummy memory cells. A process of applying the pass voltage to the unselected word lines and a stage of applying the third voltage to the dummy word line coupled with the dummy memory cells in the at least one group of dummy memory cells to turn off the corresponding dummy memory cells temporally overlap in part.

In the examples of the present disclosure, the peripheral circuit may be coupled to the array of memory cells through a bit line, a word line, a source line, the upper select line, and the lower select line. The bit line and the upper select line may intersect each other on a horizontal plane, so as to exclusively select a memory string where a memory cell to be programmed is located. The peripheral circuit may include any suitable analog, digital, and/or hybrid signal circuits for facilitating operations of the array of memory cells by applying and sensing voltage signals and/or current signals to and from each target memory cell. The peripheral circuit includes a page buffer/sense amplifier, a column decoder/bit line driver, a row decoder/word line driver, a voltage generator, a control logic, a register, an interface, and a data bus. The peripheral circuit may further include various types of circuits and electronic components formed using a metal-oxide-semiconductor (MOS) technology.

In the examples of the present disclosure, the peripheral circuit is configured to, in a first stage, ramp up a voltage on the unselected word lines to the pass voltage. The peripheral circuit is configured to, in a second stage, stabilize the voltage on the unselected word lines at the pass voltage. The first stage and a process of applying the third voltage to the dummy word line coupled with the dummy memory cells in the at least one group of dummy memory cells overlap temporally.

In the examples of the present disclosure, the peripheral circuit is configured to, in the second stage, apply a fourth voltage to the at least one dummy word line to turn on all the dummy memory cells.

In the examples of the present disclosure, the peripheral circuit is configured to, in the first stage, apply the third voltage to a dummy word line coupled with the dummy memory cells in the group of dummy memory cells nearest to the lower select transistor, and apply the fourth voltage to a dummy word line coupled with the dummy memory cells in other groups of dummy memory cells.

In the examples of the present disclosure, the plurality of memory cells include a first group of memory cells, a second group of memory cells, a third group of memory cells, a first group of dummy memory cells located between the first group of memory cells and the second group of memory cells, and a second group of dummy memory cells located between the second group of memory cells and the third group of memory cells. The peripheral circuit is configured to, in the first stage, apply the third voltage to a dummy word line coupled with the dummy memory cells in one of the first group of dummy memory cells and the second group of dummy memory cells, and apply the fourth voltage to a dummy word line coupled with the dummy memory cells in the other one of the first group of dummy memory cells and the second group of dummy memory cells; or the peripheral circuit is configured to, in the first stage, apply the third voltage to the dummy word lines coupled with the dummy memory cells in the first group of dummy memory cells and the second group of dummy memory cells.

In the examples of the present disclosure, a plurality of lower select transistors located at the same level in the different memory strings in the memory block are connected to each other and coupled to the same lower select line.

In the examples of the present disclosure, the peripheral circuit is configured to, in the prepulse operation, apply the second voltage to a selected upper select line coupled with an upper select transistor of a selected memory string.

In the examples of the present disclosure, the peripheral circuit is configured to, in the prepulse operation, apply the pass voltage or a fifth voltage to the selected word line.

In the examples of the present disclosure, the peripheral circuit is configured to: perform the prepulse operation prior to a verify operation; or the peripheral circuit is configured to perform the prepulse operation prior to a read operation; or the peripheral circuit is configured to perform the prepulse operation prior to a program operation.

In the examples of the present disclosure, the peripheral circuit is configured to, in the verify operation, apply the second voltage to an upper select transistor of a selected memory string, apply the first voltage to the upper select transistors of the unselected memory strings, and apply the second voltage to lower select transistors of both the selected memory string and the unselected memory strings; and the peripheral circuit is configured to, in the verify operation, apply a verify voltage to the selected word line, and apply a fourth voltage to the unselected word lines and the dummy word lines coupled with the dummy memory cells in all the groups of dummy memory cells.

In the examples of the present disclosure, the memory may be a NAND memory.

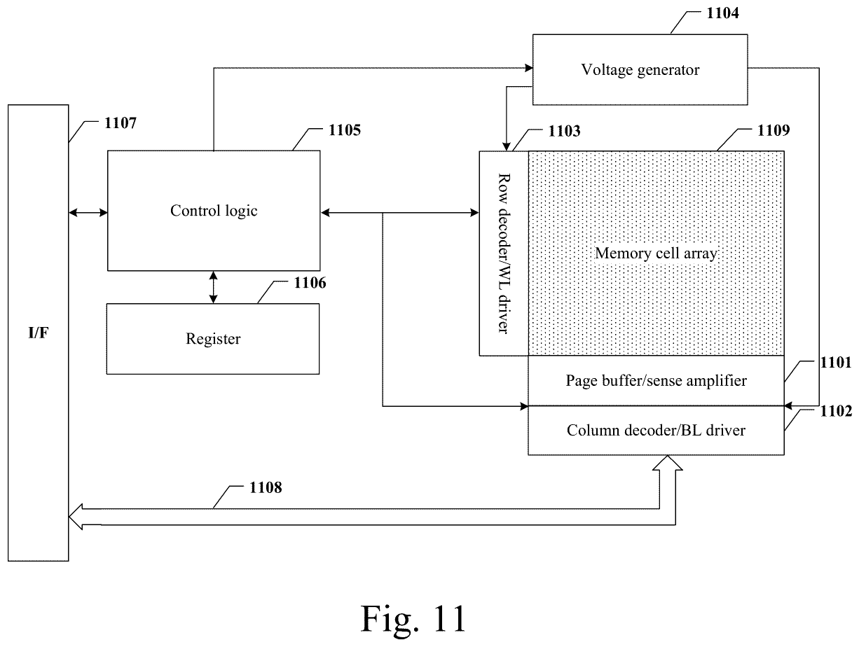

FIG. 11 is a block diagram of a memory including an array of memory cells and a peripheral circuit, according to an example of the present disclosure.

As shown in FIG. 11, the peripheral circuit includes a page buffer/sense amplifier 1101, a column decoder/bit line driver 1102, a row decoder/word line driver 1103, a voltage generator 1104, a control logic 1105, a register 1106, an interface 1107, and a data bus 1108. It is to be understood that in some examples, an additional peripheral circuit not shown in FIG. 11 may be also included.

The page buffer/sense amplifier 1101 may be configured to read and program (write) data from and to the array of memory cells 1109 according to control signals from the control logic 1105. In one example, the page buffer/sense amplifier 1101 may store one page of program data (write data) to be programmed into one page of the array of memory cells. In another example, the page buffer/sense amplifier 1101 may perform a verify operation to ensure that data is properly programmed into memory cells that are coupled to a selected word line. In yet another example, the page buffer/sense amplifier 1101 may also sense a low power signal from a bit line that represents a data bit stored in a memory cell, and amplify a small voltage swing to a recognizable logic level in a read operation. The column decoder/bit line driver 1102 may be configured to be controlled by the control logic and select one or more NAND memory strings by applying bit line voltages generated from the voltage generator.

The row decoder/word line driver 1103 may be configured to be controlled by the control logic 1105, select/deselect a memory block of the array of memory cells, and select/deselect a word line of the memory block. The row decoder/word line driver 1103 may be further configured to drive the word line using a word line voltage generated from the voltage generator 1104. As described below in detail, the row decoder/word line driver 1103 is configured to perform an erase operation on the memory cells coupled to (one or more) selected word lines. The voltage generator 1104 may be configured to be controlled by the control logic 1105 and generate a word line voltage (such as, a read voltage, a program voltage, a pass voltage, a local voltage, and a verification voltage, etc.), a bit line voltage, and a source line voltage to be supplied to the array of memory cells 1109.

The control logic 1105 may be coupled to each peripheral circuit as described above and configured to control operations of each peripheral circuit. The register 1106 may be coupled to the control logic 1105, and include a state register, a command register, and an address register for storing state information, a command operation code (OP code), and a command address that are used for controlling the operations of each peripheral circuit. The interface 1107 may be coupled to the control logic 1105, and act as a control buffer to buffer and relay control commands received from a host (not shown in FIG. 11) to the control logic 1105 and state information received from the control logic 1105 to the host. The interface 1107 may also be coupled to the column decoder/bit line driver 1102 via the data bus 1108 and act as a data I/O interface and a data buffer to buffer and relay data to and from the array of memory cells 1109.

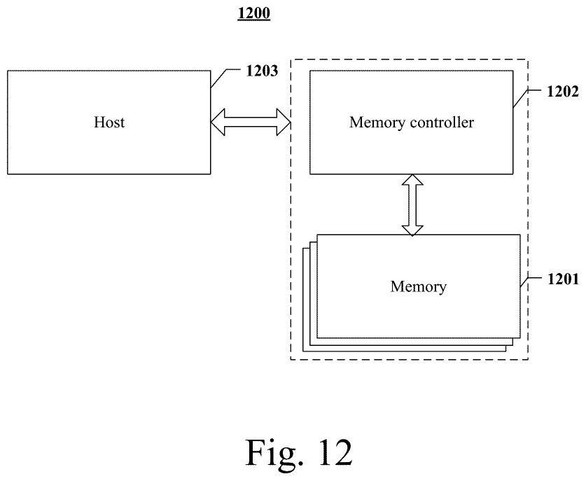

FIG. 12 is a block diagram of a memory system, according to an example of the present disclosure.

As shown in FIG. 12, the examples of the present disclosure provide a memory system 1200. The memory system 1200 includes: a memory 1201 as in the above technical solution; and a controller 1202 coupled to the memory 1201 and configured to control the memory 1201.

In the examples of the present disclosure, the controller 1202 may be coupled with the memory 1201 through a plurality of interfaces and may control operations of the memory 1201, such as read, erase, and program operations, etc. The memory system further includes a host 1203. The host 1203 may be a processor (e.g., a Central Processing Unit (CPU)) or a System on Chip (SOC) (e.g., an Application Processor (AP))) of an electronic apparatus. The host 1203 may be configured to send data to the memory 1201. Alternatively, the host 1203 may be configured to receive data from the memory 1201.

In the examples of the present disclosure, the memory system 1200 may be a mobile phone, a desktop computer, a laptop computer, a tablet, a vehicle computer, a gaming console, a printer, a positioning device, a wearable electronic device, a smart sensor, a Virtual Reality (VR) device, an Argument Reality (AR) device, or any other suitable electronic devices having storage therein.

In some examples, the controller 1202 may be designed for operating in a low duty-cycle environment, such as a Secure Digital (SD) card, a Compact Flash (CF) card, or a Universal Serial Bus (USB) flash drive, or for use in electronic apparatuses such as a personal computer, a digital camera, or a mobile phone, etc. In some other examples, the controller 1202 may be also designed for operating in a high duty-cycle environment, such as an SSD or an embedded Multi-Media Card (eMMC), which may be used as a data memory for mobile apparatuses such as a smartphone, a tablet computer, and a laptop computer, etc., and an enterprise memory array.

In some examples, the controller 1202 can manage data stored in the memory 1201 and communicate with the host. In an example, the controller 1202 may be configured to control read, erase, and program operations, etc., of the memory 1201, may be further configured to manage various functions with respect to data stored or to be stored in the memory 1201, including, but not limited to, bad-block management, garbage collection, logical-to-physical address conversion, and wear leveling, etc., and may be further configured to process an Error Correction Code (ECC) with respect to data read from or written to the memory 1201.

In some other examples, the controller 1202 may further perform any other suitable functions, e.g., formatting the memory 1201 or communicating with an external apparatus according to a particular communication protocol. In an example, the controller 1202 may communicate with the external apparatus through at least one of various interface protocols, such as a USB protocol, an MMC protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer Small Interface (SCSI) protocol, an Enhanced Small Disk Interface (ESDI) protocol, an Integrated Drive Electronics (IDE) protocol, and a Firewire protocol, etc.

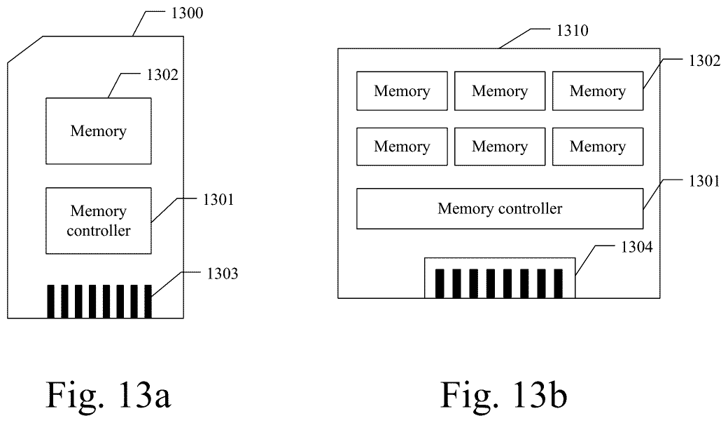

FIG. 13a is a schematic diagram of a memory card, according to an example of the present disclosure. FIG. 13b is a schematic diagram of a solid-state drive (SSD), according to an example of the.

In some examples, a memory controller 1301 and a single memory 1302 may be integrated into the memory card 1300. The memory card 1300 may include a PC card (Personal Computer Memory Card International Association (PCMCIA)), a CF card, a Smart Media (SM) card, a memory stick, a multimedia card (MMC, reduced size (RS)-MMC, and MMCmicro), an secure digital (SD) card (SD, miniSD, microSD, and SD high capacity (SDHC)), and a UFS, etc. The memory card 1300 may further include a memory card connector 1303 coupling the memory card 1300 with a host (e.g., the host 1203 in FIG. 12).

In some other examples, the memory controller 1301 and a plurality of memories 1302 may be integrated into a solid-state drive (SSD) 1310. The solid-state drive 1310 may further include a solid state drive connector 1304 coupling the solid state drive 1310 with the host (e.g., the host 1203 in FIG. 12). In some implementations, a storage capacity and/or an operating speed of the solid-state drive 1310 are greater than a storage capacity and/or an operating speed of the memory card 1300.

It is to be understood that references to “one example” or “an example” throughout this specification mean that particular features, structures, or characteristics related to the example are included in at least one example of the present disclosure. Therefore, “in one example” or “in an example” presented everywhere throughout this specification does not necessarily refer to the same example. Furthermore, these particular features, structures, or characteristics may be incorporated in one or more examples in any suitable manner. It is to be understood that, in various examples of the present disclosure, sequence numbers of the above processes do not indicate an execution sequence, and an execution sequence of various processes shall be determined by functionalities and intrinsic logics thereof, and shall constitute no limitation on an implementation process of the examples of the present disclosure. The above sequence numbers of the examples of the present disclosure are only for description, and do not represent goodness and badness of the examples.

The above descriptions are merely preferable implementations of the present disclosure, and are not intended to limit the patent scope of the present disclosure. Equivalent structure transformation made using the contents of the specification and the drawings of the present disclosure under the inventive concept of the present disclosure, or direct/indirect application to other related technical fields is encompassed within the patent protection scope of the present disclosure.

What is claimed is:

1. A method of operating a memory, comprising:
in a prepulse operation, applying a first voltage to unselected upper select line coupled with upper select transistor of unselected memory string, so as to turn off the upper select transistor of the unselected memory string, and applying a second voltage to unselected lower select line coupled with lower select transistor of the unselected memory string, so as to turn on the lower select transistor of the unselected memory string;
applying a pass voltage to unselected word line; and
applying a third voltage to a dummy word line coupled with dummy memory cell in at least one group of dummy memory cells, so as to turn off corresponding dummy memory cell,
wherein a stage of applying the pass voltage to the unselected word line and a stage of applying the third voltage to the dummy word line coupled with the dummy memory cell in the at least one group of dummy memory cells temporally overlap in part, and
wherein the memory comprises:
a memory block comprising memory strings, each of the memory strings comprising the upper select transistor, memory cells, and a lower select transistor sequentially connected in series, the memory cells comprising at least two groups of memory cells and a group of dummy memory cells located between any two adjacent groups of the memory cells;
word lines, each of the word lines coupled with corresponding memory cell;
at least one dummy word line, each dummy word line coupled with corresponding dummy memory cell;
an upper select line coupled with a corresponding upper select transistor; and
a lower select line coupled with a corresponding lower select transistor.

2. The method of claim 1, wherein the applying the pass voltage to the unselected word line comprises:
in a first stage, ramping up a voltage on the unselected word line to the pass voltage; and
in a second stage, stabilizing the voltage on the unselected word line at the pass voltage,
wherein the first stage and a process of applying the third voltage to the dummy word line coupled with the dummy memory cell in the at least one group of dummy memory cells overlap temporally.

3. The method of claim 2, further comprising:
in the second stage, applying a fourth voltage to the at least one dummy word line to turn on the corresponding dummy memory cell.

4. The method of claim 3, wherein the applying the third voltage to the dummy word line coupled with the dummy memory cell in the at least one group of dummy memory cells comprises:
in the first stage, applying the third voltage to a dummy word line coupled with the dummy memory cell in the group of dummy memory cells nearest to the lower select transistor, and applying the fourth voltage to a dummy word line coupled with the dummy memory cell in other groups of dummy memory cells.

5. The method of claim 3, wherein:
the memory cells comprise a first group of memory cells, a second group of memory cells, a third group of memory cells, a first group of dummy memory cells located between the first group of memory cells and the second group of memory cells, and a second group of dummy memory cells located between the second group of memory cells and the third group of memory cells; and
the applying the third voltage to the dummy word line coupled with the dummy memory cell in the at least one group of dummy memory cells comprises:
in the first stage, applying the third voltage to a dummy word line coupled with the dummy memory cell in one of the first group of dummy memory cells and the second group of dummy memory cells, and applying the fourth voltage to a dummy word line coupled with the dummy memory cell in the other one of the first group of dummy memory cells and the second group of dummy memory cells; or
in the first stage, applying the third voltage to the dummy word lines coupled with the dummy memory cells in the first group of dummy memory cells and the second group of dummy memory cells.

6. The method of claim 1, wherein lower select transistors located at the same level in different memory strings in the memory block are connected to each other and coupled to the same lower select line.

7. The method of claim 1, further comprising:
in the prepulse operation, applying the second voltage to a selected upper select line coupled with an upper select transistor of a selected memory string.

8. The method of claim 1, further comprising:
in the prepulse operation, applying the pass voltage or a fifth voltage to a selected word line.

9. The method of claim 1, wherein:
the prepulse operation is prior to a verify operation;
the prepulse operation is prior to a read operation; or
the prepulse operation is prior to a program operation.

10. A memory, comprising:
a memory block comprising memory strings, each of the memory strings comprising an upper select transistor, memory cells, and a lower select transistor sequentially connected in series, the memory cells comprising at least two groups of memory cells and a group of dummy memory cells located between any two adjacent groups of the memory cells;
word lines, each of the word lines coupled with corresponding memory cell;
at least one dummy word line, each dummy word line coupled with corresponding dummy memory cell;
an upper select line coupled with a corresponding upper select transistor;
a lower select line coupled with a corresponding lower select transistor; and
a peripheral circuit coupled with the word lines, the at least one dummy word line, the upper select line, and the lower select line, and the peripheral circuit being configured to:
in a prepulse operation, apply a first voltage to unselected upper select line coupled with the upper select transistor of unselected memory string, so as to turn off the upper select transistor of the unselected memory string, and apply a second voltage to unselected lower select line coupled with lower select transistor of the unselected memory string, so as to turn on the lower select transistor of the unselected memory string;
apply a pass voltage to unselected word line; and
apply a third voltage to the dummy word line coupled with the dummy memory cell in at least one group of dummy memory cells, so as to turn off the corresponding dummy memory cell,
wherein a process of applying the pass voltage to the unselected word line and a stage of applying the third voltage to the dummy word line coupled with the dummy memory cell in the at least one group of dummy memory cells to turn off the corresponding dummy memory cell temporally overlap in part.

11. The memory of claim 10, wherein the peripheral circuit is configured to:
in a first stage, ramp up a voltage on the unselected word line to the pass voltage; and
in a second stage, stabilize the voltage on the unselected word line at the pass voltage,
wherein the first stage and a process of applying the third voltage to the dummy word line connected with the dummy memory cell in the at least one group of dummy memory cells overlap temporally.

12. The memory of claim 11, wherein the peripheral circuit is configured to:
in the second stage, apply a fourth voltage to the at least one dummy word line to turn on all dummy memory cells.

13. The memory of claim 12, wherein the peripheral circuit is configured to:
in the first stage, apply the third voltage to a dummy word line coupled with the dummy memory cell in the group of dummy memory cells nearest to the lower select transistor, and apply the fourth voltage to a dummy word line coupled with the dummy memory cell in other groups of dummy memory cells.

14. The memory of claim 12, wherein:
the memory cells comprise a first group of memory cells, a second group of memory cells, a third group of memory cells, a first group of dummy memory cells located between the first group of memory cells and the second group of memory cells, and a second group of dummy memory cells located between the second group of memory cells and the third group of memory cells; and
the peripheral circuit is configured to:
in the first stage, apply the third voltage to a dummy word line coupled with the dummy memory cell in one of the first group of dummy memory cells and the second group of dummy memory cells, and apply the fourth voltage to a dummy word line coupled with the dummy memory cell in the other one of the first group of dummy memory cells and the second group of dummy memory cells; or
in the first stage, apply the third voltage to the dummy word line coupled with the dummy memory cells in the first group of dummy memory cells and the second group of dummy memory cells.

15. The memory of claim 10, wherein a plurality of lower select transistors located at the same level in different memory strings in the memory block are connected to each other and coupled to the same lower select line.

16. The memory of claim 10, wherein the peripheral circuit is configured to:
in the prepulse operation, apply the second voltage to a selected upper select line coupled with an upper select transistor of a selected memory string.

17. The memory of claim 10, wherein the peripheral circuit is configured to:
in the prepulse operation, apply the pass voltage or a fifth voltage to a selected word line.

18. The memory of claim 10, wherein the peripheral circuit is configured to:
perform the prepulse operation prior to a verify operation;
perform the prepulse operation prior to a read operation; or
perform the prepulse operation prior to a program operation.

19. The memory of claim 10, wherein the peripheral circuit is configured to:
in a verify operation, apply the second voltage to an upper select transistor of a selected memory string, apply the first voltage to the upper select transistor of the unselected memory string, and apply the second voltage to lower select transistors of both the selected memory string and the unselected memory string; and
in the verify operation, apply a verify voltage to a selected word line, and apply a fourth voltage to the unselected word line and the dummy word line coupled with the dummy memory cell in all the groups of dummy memory cells.

20. A memory system, comprising:
a memory, comprising:
a memory block comprising memory strings, each of the memory strings comprising an upper select transistor, memory cells, and a lower select transistor sequentially connected in series, the memory cells comprising at least two groups of memory cells and a group of dummy memory cells located between any two adjacent groups of the memory cells;
word lines, each of the word lines coupled with corresponding memory cell;
at least one dummy word line, each dummy word line coupled with corresponding dummy memory cell;
an upper select line coupled with a corresponding upper select transistor;
a lower select line coupled with a corresponding lower select transistor; and
a peripheral circuit coupled with the word lines, the at least one dummy word line, the upper select line, and the lower select line, and the peripheral circuit being configured to:
in a prepulse operation, apply a first voltage to unselected upper select line coupled with the upper select transistor of unselected memory string, so as to turn off the upper select transistor of the unselected memory string, and apply a second voltage to unselected lower select line coupled with lower select transistor of the unselected memory string, so as to turn on the lower select transistor of the unselected memory string;
apply a pass voltage to unselected word line; and
apply a third voltage to the dummy word line coupled with the dummy memory cell in at least one group of dummy memory cells, so as to turn off the corresponding dummy memory cell,
wherein a process of applying the pass voltage to the unselected word line and a stage of applying the third voltage to the dummy word line coupled with the dummy memory cell in the at least one group of dummy memory cells to turn off the corresponding dummy memory cells temporally overlap in part; and
a controller coupled to the memory and configured to control the memory.
